(19) United States
(12) Patent Application Publication
(10) Pub. No.: US 2016/0141381 A1
(43) Pub. Date: May 19, 2016

(54) SEMICONDUCTOR DEVICES AND METHODS FOR FABRICATING THE SAME

(71) Applicant: Samsung Electronics Co., Ltd., Suwon-si (KR)

(72) Inventors: Kook-Tae KIM, Hwaseong-si (KR); Ho-Sung Son, Hwaseong-si (KR); Geo-Myung Shin, Seoul (KR); Dong-Suk Shin, Yongin-si (KR); Si-Hyung Lee, Suwon-si (KR); Ji-Hye Yi, Suwon-si (KR); Sung-Hoon Jung, Hwaseong-si (KR); Yeong-Jong Jeong, Yongin-si (KR)

(21) Appl. No.: 14/816,568

(22) Filed: Aug. 3, 2015

(30) Foreign Application Priority Data
Nov. 19, 2014 (KR) 10-2014-0161942

(51) Int. Cl. H01L 29/423; H01L 29/08; H01L 29/51; H01L 29/78

(52) U.S. Cl. CPC H01L 29/42364; H01L 29/7851; H01L 29/0847; H01L 29/51; H01L 29/518

(57) ABSTRACT

Semiconductor devices and methods for fabricating the same are provided. The semiconductor devices include a fin active pattern formed to project from a substrate, a gate electrode formed to cross the fin active pattern on the substrate, a gate spacer formed on a side wall of the gate electrode and having a low dielectric constant and an elevated source/drain formed on both sides of the gate electrode on the fin active pattern. The gate spacer includes first, second and third spacers that sequentially come in contact with each other in a direction in which the gate spacer goes out from the gate electrode, and a carbon concentration of the second spacer is lower than carbon concentrations of the first and third spacers.

### CROSS-REFERENCE TO RELATED APPLICATION

This application is based on and claims priority under 35 U.S.C. §119 to Korean Patent Application No. 10-2014-0161942, filed on Nov. 19, 2014 in the Korean Intellectual Property Office, the disclosure of which is incorporated herein in its entirety by reference.

### FIELD

The present inventive concept relates to a semiconductor device and a method for fabricating the same.

### BACKGROUND

TO increase a density of semiconductor devices, a multi-gate transistor has been proposed. The multi-gate transistor includes a fin-shaped or nanowire-shaped silicon body formed on a substrate and a gate is formed on a surface of the silicon body.

Since the multi-gate transistor uses a three-dimensional (3D) channel, it is easy to increase an integration density. Further, current control capability can be improved without increasing a gate length of the multi-gate transistor. In addition, a short channel effect (SCE) that an electric potential of a channel region is affected by a drain voltage can be effectively suppressed.

### SUMMARY

One subject to be solved by the present inventive concept is to provide a semiconductor device, which includes a gate spacer that is formed using a low-k material in a fin structure, and thus can improve the operation performance of the semiconductor device through reduction of a capacitive coupling phenomenon between a gate and a source and/or a drain and suppression of an abnormal growth of an epitaxial layer.

Another subject to be solved by the present inventive concept is to provide a method for fabricating a semiconductor device, which includes a gate spacer that is formed using a low-k material in a fin structure, and thus can improve the operation performance of the semiconductor device through reduction of a capacitive coupling phenomenon between a gate and a source and/or a drain and suppression of an abnormal growth of an epitaxial layer.

Additional advantages, subjects, and features of the invention will be set forth in part in the description which follows and in part will become apparent to those having ordinary skill in the art upon examination of the following or may be learned from practice of the invention.

According to an aspect of the present inventive concept, there is provided a semiconductor device comprising a fin active pattern formed to project from a substrate, a gate electrode formed to cross the fin active pattern on the substrate, a gate spacer formed on a side wall of the gate electrode and having a low dielectric constant and an elevated source/drain formed on both sides of the gate electrode on the fin active pattern, wherein the gate spacer includes first, second and third spacers that sequentially come in contact with each other in a direction in which the gate spacer goes out from the gate electrode, and a carbon concentration of the second spacer is lower than carbon concentrations of the first and third spacers.

According to another aspect of the present inventive concept, there is provided a semiconductor device comprising a fin active pattern formed to project from a substrate, a gate electrode formed to cross the fin active pattern on the substrate, a gate spacer formed on a side wall of the gate electrode and having a low dielectric constant and an elevated source/drain formed on both sides of the gate electrode on the fin active pattern, wherein the gate spacer includes first and second spacers that sequentially come in contact with each other in a direction in which the gate spacer goes out from the gate electrode, and an oxygen concentration of the first spacer is lower than an oxygen concentration of the second spacer.

### BRIEF DESCRIPTION OF THE DRAWINGS

The above and other objects, features and advantages of the present inventive concept will be more apparent from the following detailed description taken in conjunction with the accompanying drawings, in which:

FIG. 1 is a perspective view illustrating a semiconductor device according to embodiments of the present inventive concept;

FIG. 2 is a perspective view illustrating the semiconductor device of FIG. 1 with an interlayer insulating layer omitted;

FIG. 3 is a cross-sectional view of the semiconductor device of FIG. 2 taken along the line A-A of FIG. 2;

FIG. 4 is an enlarged cross-sectional view of a portion B of the semiconductor device of FIG. 3;

FIG. 5 is a graph illustrating a SIMS (Secondary Ion Mass Spectroscopy) profile of a carbon concentration of a gate spacer of FIG. 4;

FIG. 6 is a graph illustrating a SIMS (Secondary Ion Mass Spectroscopy) profile of an oxygen concentration of a gate spacer of FIG. 4;

FIG. 7 is a block diagram of an electronic system that includes a semiconductor device according to some embodiments of the present inventive concept;

FIGS. 8 and 9 are examples of semiconductor systems to which a semiconductor device according to some embodiments of the present inventive concept can be applied;

FIGS. 10 to 25 are views illustrating intermediate steps of a method for fabricating a semiconductor device according to some embodiments of the present inventive concept;

FIG. 26 is a cross-sectional view of a semiconductor device according to some embodiments of the present inventive concept;

FIGS. 27 to 29 are views illustrating intermediate steps of a method for fabricating a semiconductor device according to some embodiments of the present inventive concept; and

FIG. 30 is a cross-sectional view of a semiconductor device according to some embodiments of the present inventive concept.

### DETAILED DESCRIPTION OF THE EMBODIMENTS

The present inventive concept will now be described more fully hereinafter with reference to the accompanying drawings, in which preferred embodiments of the invention are shown. The present inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art. The same reference numbers indicate the same components throughout the specification. In the attached figures, the thickness of layers and regions may be exaggerated for clarity.

It will be understood that when an element or layer is referred to as being “connected to,” or “coupled to” another element or layer, it can be directly connected to or coupled to another element or layer or intervening elements or layers may be present. In contrast, when an element is referred to as being “directly connected to” or “directly coupled to” another element or layer, there are no intervening elements or layers present. As used herein, the term “and/or” includes any and all combinations of one or more of the associated listed items.

It will also be understood that when a layer is referred to as being “on” another layer or substrate, it can be directly on the other layer or substrate, or intervening layers may also be present. In contrast, when an element is referred to as being “directly on” another element, there are no intervening elements present.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present inventive concept.

The use of the terms “a” and “an” and “the” and similar referents in the context of describing some embodiments of the present inventive concept (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which this invention belongs. It is noted that the use of any and all examples, or terms provided herein is intended merely to better illuminate the inventive concept and is not a limitation on the scope of the inventive concept unless otherwise specified. Further, unless defined otherwise, all terms defined in generally used dictionaries may not be overly interpreted.

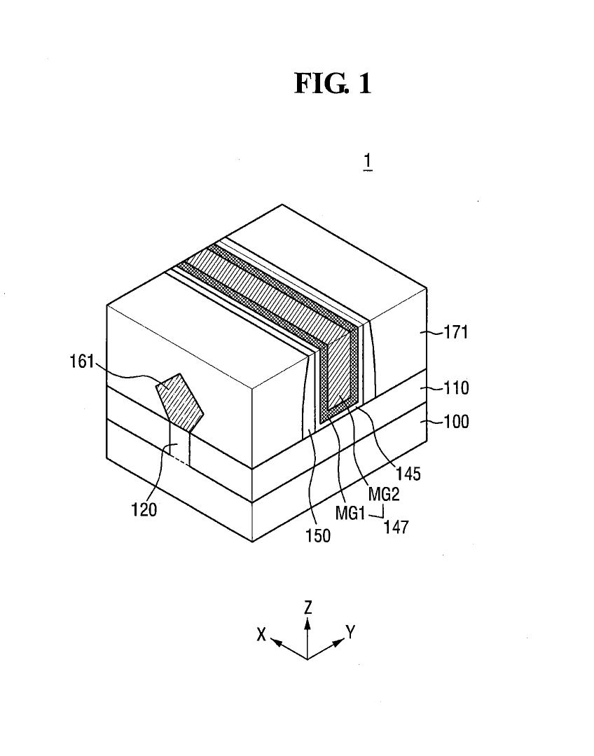

Hereinafter, referring to FIGS. 1 to 6, a semiconductor device according to some embodiments of the present inventive concept will be described.

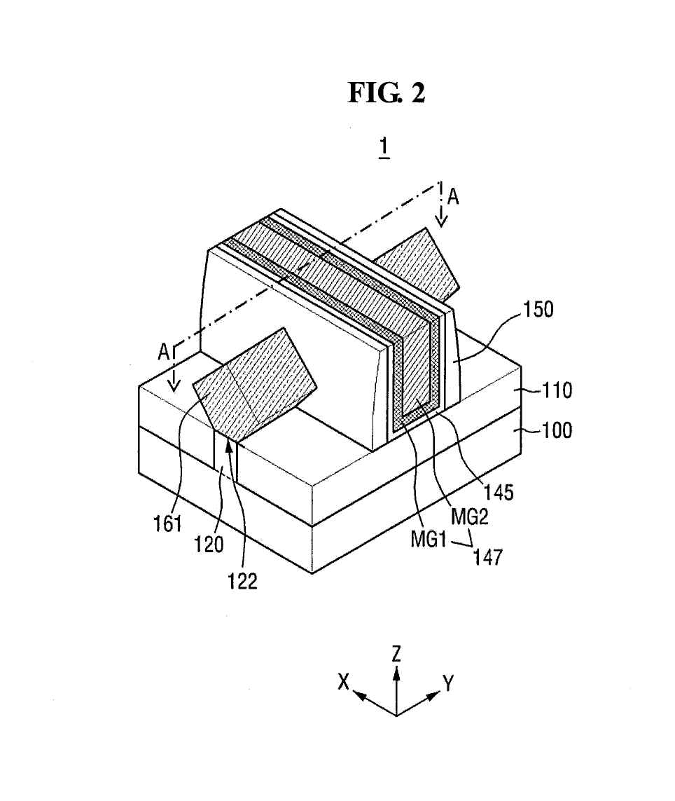

FIG. 1 is a perspective view illustrating a semiconductor device according to some embodiments of the present inventive concept, and FIG. 2 is a perspective view illustrating the semiconductor device of FIG. 1 with an interlayer insulating layer omitted.

Referring to FIGS. 1 and 2, a semiconductor device 1 according to some embodiments of the present inventive concept includes a substrate 100, a fin active pattern 120, a gate electrode 147, a first gate spacer 150, an elevated source/drain 161, and an interlayer insulating layer 171.

The substrate 100 may be made of, for example, bulk silicon or SOI (Silicon-On-Insulator). In some embodiments, the substrate 100 may be a silicon substrate, or may include another material, such as silicon germanium, indium antimonide, lead telluride, indium arsenide, indium phosphide, gallium arsenide, or gallium antimonide. Further, the substrate 100 may be provided by forming an epitaxial layer on a base substrate.

The fin active pattern 120 may project from the substrate 100. Since a field insulating layer 110 is formed on the substrate, it may cover a part of a side surface of the fin active pattern 120. A part of an upper surface of the fin active pattern 120 may form the same plane as an upper surface of the field insulating layer 110 that is formed on the substrate 100, but is not limited thereto. The fin active pattern 120 may project from the field insulating layer 110. Specifically, a portion of the fin active pattern 120, on which the gate electrode 147 is formed, may project from the field insulating layer 110, but a portion on which the elevated source/drain 161 is formed may not project. In some embodiments, the portion on which the elevated source/drain 161 is formed may also project from the field insulating layer 110.

The fin active pattern 120 may extend in a second direction Y. The fin active pattern 120 may be a part of the substrate 100 and may include an epitaxial layer that is grown from the substrate 100.

The gate electrode 147 may be formed to cross the fin active pattern 120 on the fin active pattern 120. That is, the gate electrode 147 may be formed on the field insulating layer 110. The gate electrode 147 may extend in a first direction X.

The gate electrode 147 may include metal layers MG1 and MG2. As illustrated, the gate electrode 147 may include two or more laminated metal layers MG1 and MG2. The first metal layer MG1 serves to adjust a work function, and the second metal layer MG2 serves to fill a space that is formed by the first metal layer MG1. For example, the first metal layer MG1 may include at least one of TiN, TaN, TiC, and TaC. Further, the second metal layer MG2 may include W or Al. Further, the gate electrode 147 may be made of Si or SiGe that is not metal. The gate electrode 147 as described above may be formed through a replacement process, but is not limited thereto.

The gate insulating layer 145 may be formed between the fin active pattern 120 and the gate electrode 147. The gate insulating layer 145 may be formed on an upper surface and an upper portion of a side surface of the fin active pattern 120. Further, the gate insulating layer 145 may be arranged between the gate electrode 147 and the field insulating layer 110. The gate insulating layer 145 may include a high-k material having a higher dielectric constant than the dielectric constant of a silicon oxide layer. For example, the gate insulating layer 145 may include at least one of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, but is not limited thereto.

The first gate spacer 150 may be formed on a sidewall of the gate electrode 147 that extends in the first direction X, and specifically, on a sidewall of the gate insulating layer 145. Although it is illustrated that the first gate spacer 150 is a single layer, it may have a multilayer structure.

The first gate spacer 150 has a low dielectric constant. Here, “the gate spacer has a low dielectric constant” means that a dielectric constant of dielectric materials in the multilayer structure that constitutes the first gate spacer 150 is the low dielectric constant.

In a semiconductor device according to some embodiments of the present inventive concept, the dielectric constant of the first gate spacer 150 may equal to or higher than about 3.8 and equal to or lower than about 5.5.

Since the first gate spacer 150 is formed of a material having a low dielectric constant, capacitive coupling between the gate electrode 147 and the elevated source/drain 161 can be reduced. Through reduction of the capacitive coupling, the AC performance of the semiconductor device 1 can be improved.

The elevated source/drain 161 may be formed on both sides of the gate electrode 147 and on the fin active pattern 120. In other words, the elevated source/drain 161 may be formed in a recess 122 that is formed in the fin active pattern 120.

The elevated source/drain 161 may have various shapes. For example, the elevated source/drain 161 may have at least one of a diamond shape, a circular shape, and a rectangular shape. For example, FIGS. 1 and 2 illustrate a diamond shape (or pentagonal shape or hexagonal shape).

In the case where the semiconductor device 1 is a PMOS fin transistor, the source/drain 161 may include a compressive stress material. For example, in comparison to Si, the compressive stress material may be a material having a high lattice constant and may be, for example, SiGe. The compressive stress material may apply compressive stress to the fin active pattern 120 to improve carrier mobility of a channel region.

In the case where the semiconductor device 1 is an NMOS fin transistor, the source/drain 161 may be made of the same material as the substrate 100 or may be made of a tensile stress material. For example, in the case where the substrate 100 is made of Si, the source/drain 161 may be Si or a material having a lower lattice constant than the lattice constant of Si (e.g., SiC).

The interlayer insulating layer 171 may include at least one of a low-k material, an oxide layer, a nitride layer, and an oxynitride layer. The low-k material may be FOX (Flowable Oxide), TOSZ (Tonen SilaZen), USG (Undoped Silica Glass), BSG (Gorosilica Glass), PSG (PhosphoSilica Glass), BPSG (BoroPhosphoSilica Glass), PRTEOS (Plasma Enhanced Tetra Ethyl Ortho Silicate), FSG (Fluoride Silicate Glass), HOP (High Density Plasma), PEPS (Plasma Enhanced Oxide), FCVD (Flowable CVD), or a combination thereof.

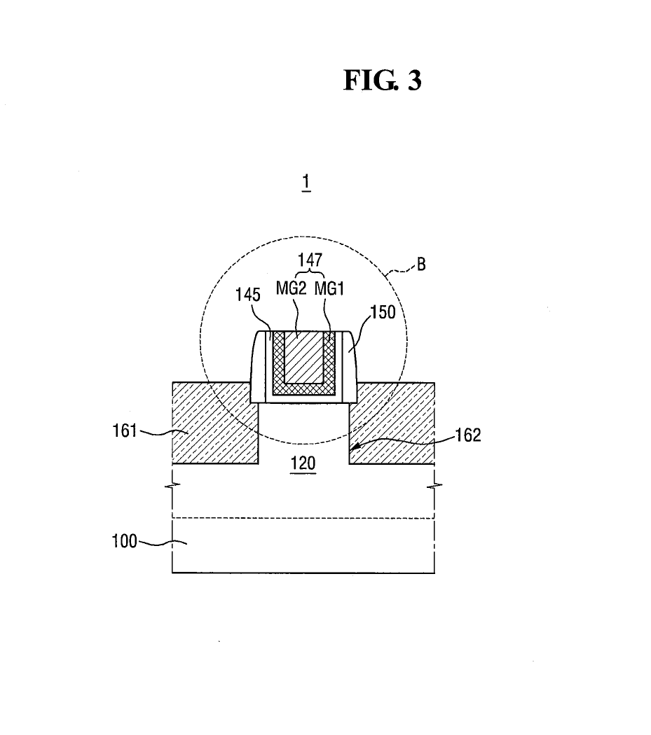

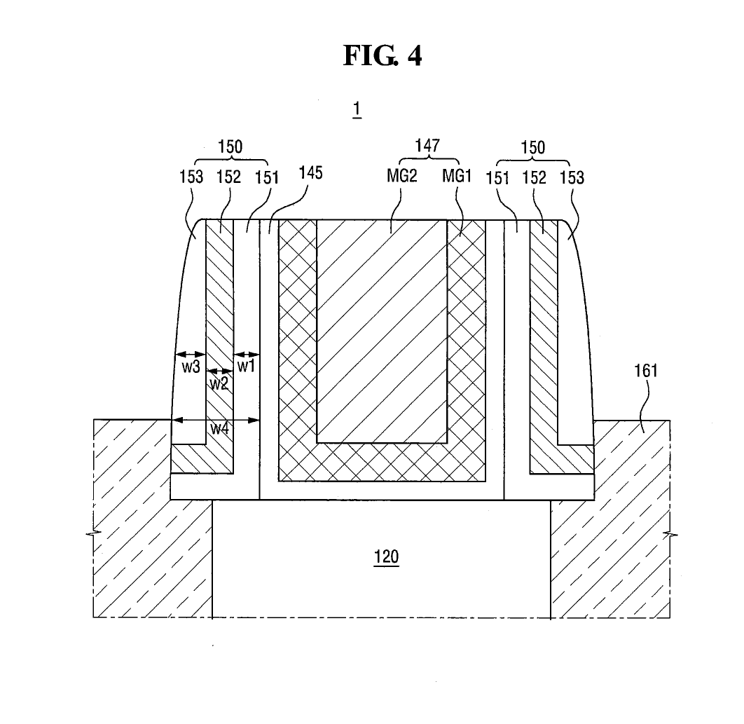

FIG. 3 is a cross-sectional view of the semiconductor device of FIG. 2 taken along the line A-A of FIG. 2, and FIG. 4 is an enlarged cross-sectional view of a portion 13 of the semiconductor device of FIG. 3.

Referring to FIGS. 3 and 4, the first gate spacer 150 of the semiconductor device 1 of FIG. 1 may include a first spacer 151, a second spacer 152, and a third spacer 153.

The first spacer 151 may be positioned most adjacently to the gate electrode 147 on the innermost wall of the first gate spacer 150, but is not limited thereto. Another layer may be formed between the first spacer 151 and the gate electrode 147. That is, the first spacer 151 may be positioned on an inner side than the second spacer 152 and the third spacer 153, i.e., on a side that is close to the gate electrode 147.

The first spacer 151 may include SiN or SiCN that includes carbon. The first spacer 151 may also include oxygen. That is, the first spacer 151 may include SiOCN or SiOC.

The first spacer 151 may be in an “L” shape. That is, an extending portion may be formed in a horizontal direction in which the first spacer 151 goes out from the gate electrode 147. The “L” shape may be formed in a process of depositing three layers that constitute the first gate spacer 150 at the same time and then etching the deposited layers. This process will be described in detail later.

The second spacer 152 may be positioned in the middle of the first gate spacer 150. That is, the second spacer 152 may be formed between the first spacer 151 and the third spacer 153. That is, the second spacer 152 may be positioned on an outer side than the first spacer 151, i.e., on a side that is far from the gate electrode 147, and may be positioned on an inner side than the third spacer 153, i.e., on a side that is close to the gate electrode 147. The second spacer 152 may come in direct contact with the first spacer 151 and the third spacer 153. Accordingly, the first gate spacer 150 may be in a triple-layer shape.

The second spacer 152 may include SiOCN or SiOC that includes carbon and oxygen. The second spacer 152 includes a similar material to the material of the first spacer 151, but the ratios of constituent elements thereof may differ from each other. Specifically, the ratio of Si, O, C, or N of the second spacer 152 may different from that of the first spacer 151.

For example, the second spacer 152 may have a carbon concentration of about 0% to about 6% and an oxygen concentration of about 35% to about 50%.

The second spacer 152 may be in an “L” shape. That is, an extending portion may be formed in a horizontal direction in which the second spacer 152 goes out from the gate electrode 147. As illustrated, the second spacer 152 may be positioned on an upper surface of an outer side of the first spacer 151.

The third spacer 153 may be positioned on the outermost wall of the first gate spacer 150. That is, the third spacer 153 may be positioned on an outer side than the first spacer 151 and the second spacer 152, i.e., on a side that is far from the gate electrode 147.

The third spacer 153 may include SiN or SiCN that includes carbon. The third spacer 153 may also include oxygen. That is, the third spacer 153 may include SiOCN or SiOC.

The third spacer 153 may be in an “I” shape. That is, the third spacer 153 may be formed only in a vertical shape without the extending portion formed in the horizontal direction in which the third spacer 153 goes out from the gate electrode 147. The side surface of the third spacer 153 may have a vertical shape or may have a slope. That is, the third spacer 153 may be in a tapered shape.

The first spacer 151 and the third spacer 153 may be substantially the same layers. That is, the first spacer 151 and the third spacer 153 may include materials having the same concentration. In contrast, the second spacer 152 may include materials having different concentration from the concentration of the materials of the first spacer 151 and the third spacer 153. In this case, the term “the same concentration” may include a fine difference in concentration between the materials.

The first spacer 151 and the third spacer 153 may have carbon concentrations of about 6% to about 21% and oxygen concentrations of about 25% to about 40%. However, the concentrations of carbon and oxygen are not limited thereto. That is, the first spacer 151 and the third spacer 153 have higher carbon concentrations than the carbon concentration of the second spacer 152 and lower oxygen concentrations than the oxygen concentration of the second spacer 152.

Processes of forming the first spacer 151 and the third spacer 153 may be performed in completely the same conditions or similar conditions. For example, the membrane of the first spacer 151 may be formed at 600° C., and the membrane of the third spacer 153 may be formed at 630° C.

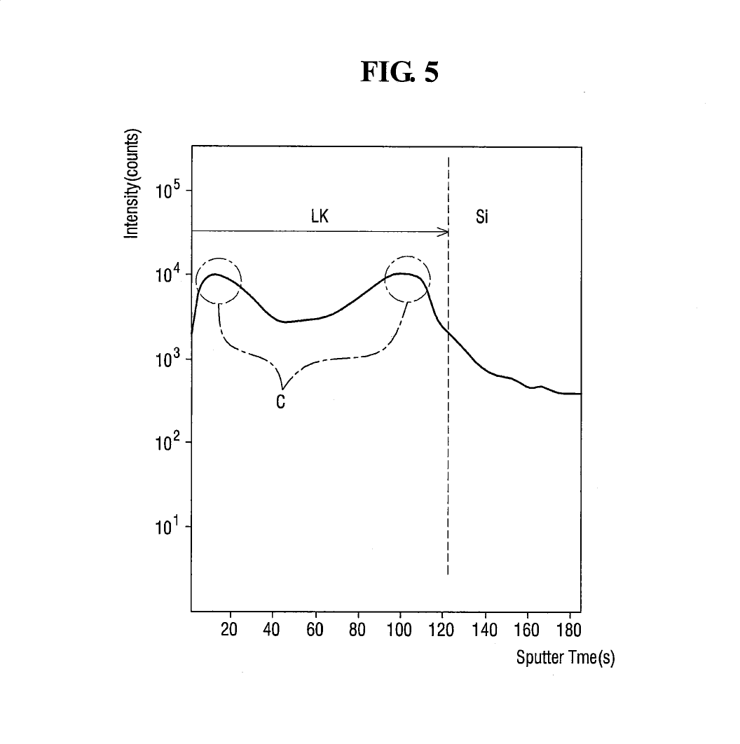

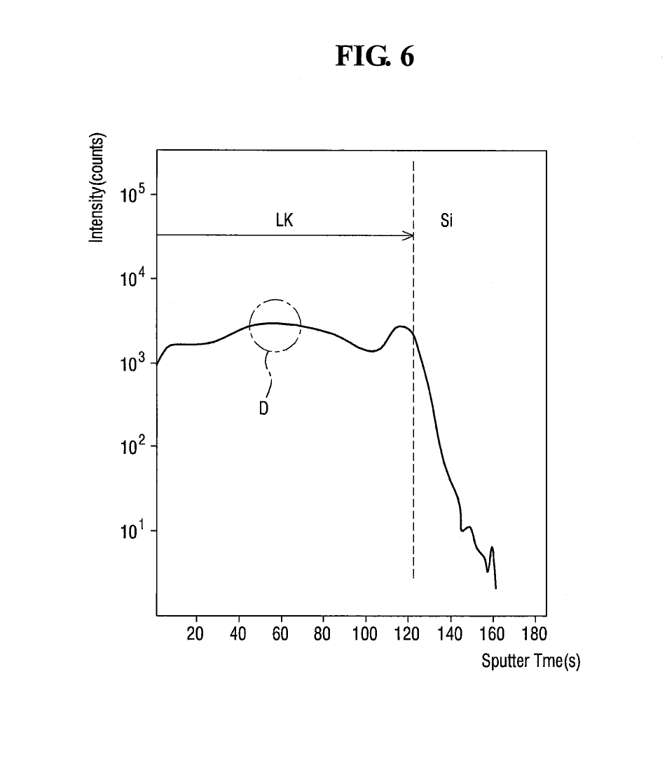

FIG. 5 is a graph illustrating a SIMS (Secondary Ion Mass Spectroscopy) profile of a carbon concentration of a gate spacer of FIG. 4, and FIG. 6 is a graph illustrating a SIMS (Secondary Ion Mass Spectroscopy) profile of an oxygen concentration of a gate spacer of FIG. 4.

Specifically, referring to FIGS. 5 and 6, the first spacer 151 and the third spacer 153 may be layers having sufficient carbon in comparison to the second spacer 152. Further, the first spacer 151 and the third spacer 153 may be layers having less sufficient oxygen in comparison to the second spacer 152. That is, the carbon concentration of the second spacer 152 may be lower than the carbon concentrations of the first spacer 151 and the third spacer 153, and the oxygen concentration of the second spacer 152 may be higher than the oxygen concentrations of the first spacer 151 and the third spacer 153.

Referring to FIG. 5, it can be seen that portions where the first spacer 151 and the third spacer 153 are positioned have considerably high carbon concentrations in comparison to the second spacer 152 (see portion C of FIG. 5). Referring to FIG. 6, a portion where the second spacer 152 is positioned has a considerably high oxygen concentration in comparison to the first spacer 151 and the third spacer 153 (see portion D of FIG. 6). The dielectric constant may be changed depending on the composition of included materials, and thus the dielectric constant of the second spacer 152 may be lower than the dielectric constant of the first spacer 151 and the third spacer 153.

In the first gate spacer 150 of the semiconductor device 1 according to some embodiments of the present inventive concept, the etch rate of the first spacer 151 and the third spacer 153 may be different from the etch rate of the second spacer 152 depending on the carbon and oxygen concentrations.

In the case of the first spacer 151 and the third spacer 153 having relatively high carbon concentrations, the wet etch rate thereof may be lower than that of the second spacer 152. In contrast, in the case of the second spacer 152 having a relatively low carbon concentration, the wet etch rate thereof may be higher than that of the first spacer 151 and the third spacer 153.

For example, the second spacer 152 that is formed through a deposition process at 600° C. may have the wet etch rate of about 32.6±5 Å/min on a wet etching surface by 100:1 HF. The first spacer 151 and the third spacer 153 that are formed through a deposition process at 600° C. may have the wet etch rate of about 5.9±2 Å/min on a wet etching surface by 100:1 HF.

Further, the second spacer 152 that is formed through a deposition process at 630° C. may have the wet etch rate of about 25.5±5 Å/min on a wet etching surface by 100:1 HF. The first spacer 151 and the third spacer 153 that are formed through a deposition process at 630° C. may have the wet etch rate of about 4.0±2 Å/min on a wet etching surface by 100:1 HF.

That is, the first spacer 151 and the third spacer 153 as described above may endure well against the wet etching.

Further, in the case of the first spacer 151 and the third spacer 153 having relatively low oxygen concentrations, the dry etch rate thereof may be higher than that of the second spacer 152. In contrast, in the case of the second spacer 152 having a relatively high oxygen concentration, the dry etch rate thereof may be lower than that of the first spacer 151 and the third spacer 153. Accordingly, the second spacer 152 can endure well against the dry etching.

The first gate spacer 150 may be formed by first forming a spacer layer and making a vertical portion thereof remain through the dry etching. However, in the process of forming the first gate spacer 150, a shoulder loss of the first gate spacer 150 may unintentionally occur, i.e., the vertical height of the first gate spacer 150 may be reduced greater than that as intended.

The first gate spacer 150 serves to possibly prevent a dummy gate that includes a polysilicon layer from being exposed in a gate last process. However, if the shoulder loss occurs as described above, the polysilicon layer of the dummy gate may be exposed.

The elevated source/drain 161 of the semiconductor device 1 is formed using an epitaxial growth. In this case, since the polysilicon layer includes a crystal plane like monocrystalline silicon, a semiconductor pattern is grown even on the exposed polysilicon layer. As described above, the semiconductor pattern that is parasitically formed on an upper portion of a dummy gate structure causes a nodule defect and the like. Due to such a nodule defect, the operation performance of the semiconductor device is deteriorated, and the processing yield is also lowered.

Accordingly, the first gate spacer 150 of the semiconductor device 1 according to some embodiments of the present inventive concept may have the low dry etch rate through the second spacer 152. That is, since the second spacer 152 has the low dry etch rate, the shoulder loss can be possibly prevented from occurring due to the dry etching in the process of forming the first gate spacer 150. Accordingly, in the case where a plurality of gate electrodes 147 is provided, a short circuit, i.e., a nodule defect, can be reduced or possibly prevented from occurring.

The first gate spacer 150 may be formed by depositing three layers at a time and etching the deposited layers at a time to form a triple layer. This method can reduce waste of processes in comparison to the method in which spacers are formed one by one, and can possibly prevent other patterns from being damaged due to excessive etching.

Accordingly, the first spacer 151 and the second spacer 152 may be in an “L” shape. Since the second spacer 152 is in an “L” shape, the lower portion of the first gate spacer 150 may be weakened by the wet etching. According to the method for fabricating a semiconductor device 1 according to some embodiments of the present inventive concept, the wet etching may be used at least once in the process of forming a replacement metal gate. Accordingly, the lower portion of the first gate spacer 150 may be damaged to cause the gate electrode 147 (in FIG. 4) and the elevated source/drain 161 that are subsequently formed to be short-circuited.

Specifically, it is general that the polysilicon layer of the dummy gate and the gate electrode 147 (in FIG. 4) are vertically formed as illustrated in FIG. 4, but they may not be vertically formed. That is, they may be formed in a state where a space of the lower portion thereof becomes wider than a space of the upper portion thereof. In this case, a projection portion of an additional polysilicon layer that is called a poly tailing may be formed in the space of the lower portion.

Through the poly tailing that is formed to project from the lower portion of the polysilicon layer, the lower portion of the first gate spacer 150 that is formed on both side surfaces of the dummy gate may have a thickness that is relatively thinner than the thickness of other portions of the first gate spacer 150.

Accordingly, while the polysilicon layer is removed in the process of forming a replacement metal gate, the inner sidewall of the first gate spacer 150 may be damaged, and a path, through which the gate electrode 147 (in FIG. 4) and the elevated source/drain 161 meet each other, may be formed in the lower portion of the first gate spacer 150 that has a thin thickness due to the poly tailing.

Accordingly, the gate electrode 147 (in FIG. 4) and the elevated source/drain 161 may be short-circuited through the formed path. As a result, the operation performance of the semiconductor device may be deteriorated and the processing yield may also be lowered.

Accordingly, to possibly prevent this, the semiconductor device 1 according to some embodiments of the present inventive concept includes the first gate spacer 150 in which the first spacer 151 is positioned in the second spacer 152 to possibly prevent the damage thereof even in the case where the wet etching is performed. That is, since the semiconductor device 1 according to some embodiments of the present inventive concept can reduce the capacitive coupling through a low dielectric constant, the AC performance of the semiconductor device 1 can be improved. Further, in the dry and wet etching processes, the upper portion and the lower portion of the first gate spacer 150 can be possibly prevented from being unintentionally damaged, and thus the yield of the semiconductor device 1 can be possibly prevented from being deteriorated.

Referring again to FIG. 4, the first spacer 151 may be formed with a first width W1, and the second spacer 152 may be formed with a second width W2. Further, the third spacer 153 may be formed with a third width W3. The first gate spacer 150 may be formed with a fourth width W4. In this case, the first to fourth widths W1 to W4 may not be constant, and may mean representative values, such as average values or middle values, but are not limited thereto.

For example, the fourth width W4 may be about 110 to about 150 Å. The width of the whole first gate spacer 150 may be constant to protect an internal structure against a plurality of etching processes. Further, the fourth width W4 of the first gate spacer 150 may be thinner than a predetermined thickness in consideration of the whole overlap margin.

For example, the first width W1 may be about 20 to about 50 Å. A fine pinhole may be formed in the first spacer 151. The pinhole is a hole that is formed in the first spacer 151, and in order for the first spacer 151 to perform insulation function, the thickness of the first spacer 151 may be equal to or larger than a predetermined thickness. Further, the first spacer 151 may be thinner than a predetermined thickness in consideration of the overlap margin.

For example, the third width W3 may be about 20 to about 60 Å. Since the third spacer 153 also has a pinhole, the thickness of the third spacer 153 may be equal to or larger than a predetermined thickness in the same manner as the first spacer 151. Further, in order to protect the internal structure against external etching processes, the third width W3 may be larger than the first width W1, but is not limited thereto.

For example, the second width W2 may be about 30 to about 100 Å. The second spacer 152 may be determined in consideration of the existence of the pinhole and the whole thickness of the first gate spacer 150, i.e., limitation of the fourth width W4, but is not limited thereto.

Since the semiconductor device 1 according to some embodiments of the present inventive concept reduces the capacitive coupling through the low dielectric constant of the first gate spacer 150, the AC performance of the semiconductor device 1 can be improved. Further, in the dry and wet etching processes, the upper portion and the lower portion of the first gate spacer 150 can be reduced or possibly prevented from being unintentionally damaged, and thus the yield of the semiconductor device 1 can be possibly prevented from being deteriorated.

Next, an example of an electronic system that uses the semiconductor device as described above with reference to FIGS. 1 to 6 will be described.

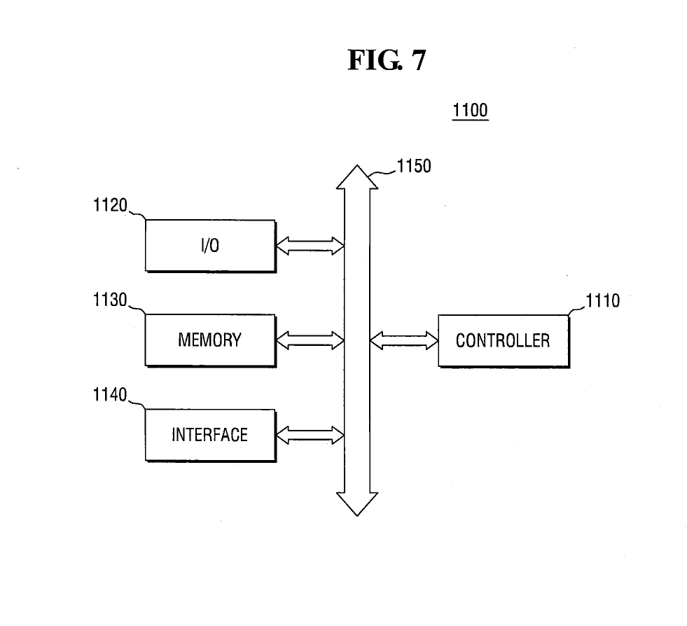

FIG. 7 is a block diagram of an electronic system that includes the semiconductor device according to some embodiments of the present inventive concept.

Referring to FIG. 7, an electronic system 1100 according to some embodiments of the present inventive concept may include a controller 1110, an input/output (I/O) device 1120, a memory 1130, an interface 1140, and a bus 1150. The controller 1110, the I/O device 1120, the memory 1130, and/or the interface 1140 may be coupled to one another through the bus 1150. The bus 1150 corresponds to paths through which data is transferred.

The controller 1110 may include at least one of a microprocessor, a digital signal processor, a microcontroller, and logic elements that can perform similar functions. The I/O device 1120 may include a keypad, a keyboard, and a display device. The memory 1130 may store data and/or commands. The interface 1140 may function to transfer the data to a communication network or receive the data from the communication network. The interface 1140 may be of a wired or wireless type. For example, the interface 1140 may include an antenna or a wire/wireless transceiver. Although not illustrated, the electronic system 1100 may further include a high-speed DRAM and/or SRAM as an operating memory for improving the operation of the controller 1110. The semiconductor device according to some embodiments of the present inventive concept may be provided in the memory 1130, or may be provided as a part of the controller 1110 or the I/O device 1120.

The electronic system 1100 may be applied to a PDA (Personal Digital Assistant), a portable computer, a web tablet, a wireless phone, a mobile phone, a digital music player, a memory card, or all electronic devices that can transmit and/or receive information in wireless environments.

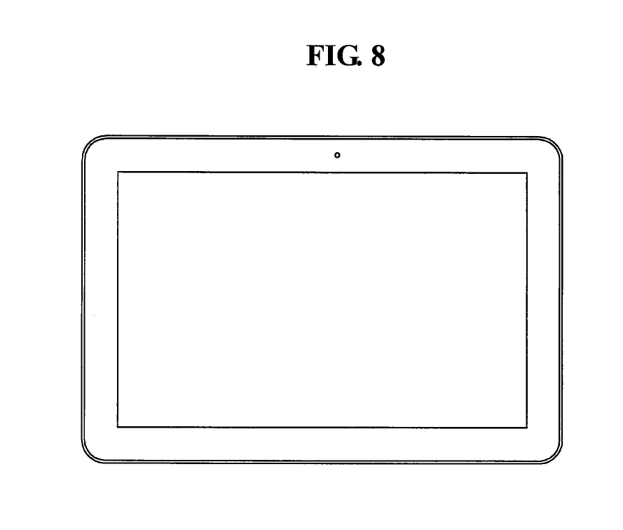

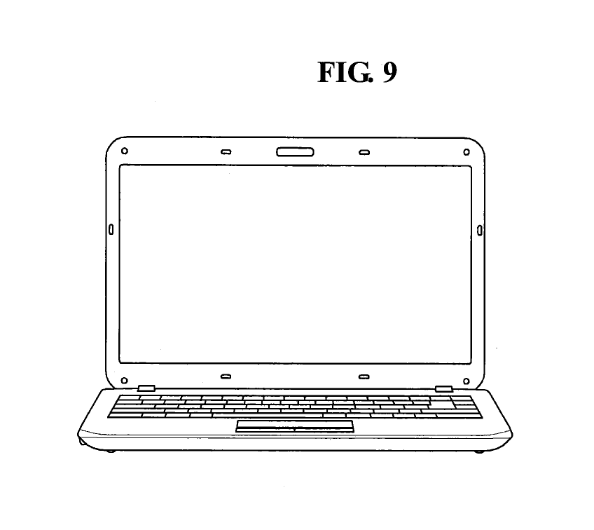

FIGS. 8 and 9 are examples of semiconductor systems to which the semiconductor device according to some embodiments of the present inventive concept can be applied. FIG. 8 illustrates a tablet PC and FIG. 9 illustrates a notebook computer. At least one of the semiconductor devices according to some embodiments of the present inventive concept may be used in the tablet PC or the notebook computer. It is apparent to those skilled in the art that the semiconductor device according to some embodiments of the present inventive concept can be applied even to other integrated circuit devices that have not been exemplified.

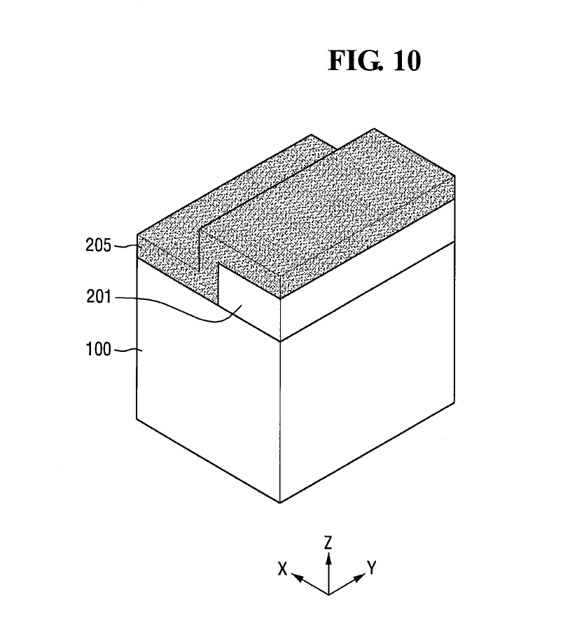

Hereinafter, referring to FIGS. 10 to 25, a method for fabricating a semiconductor device according to some embodiments of the present inventive concept will be described.

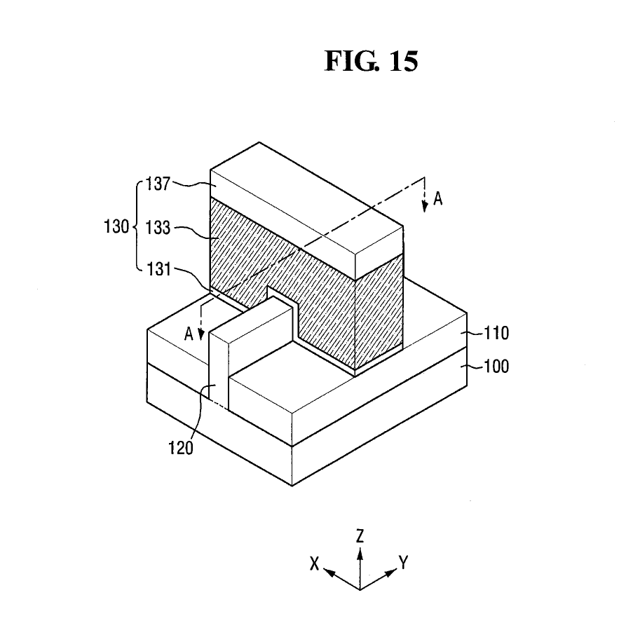

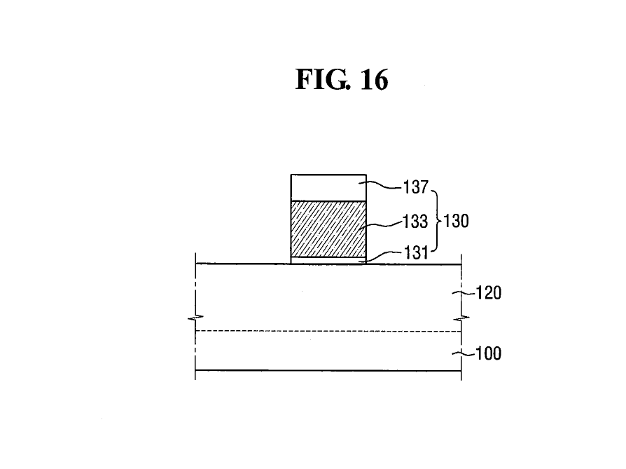

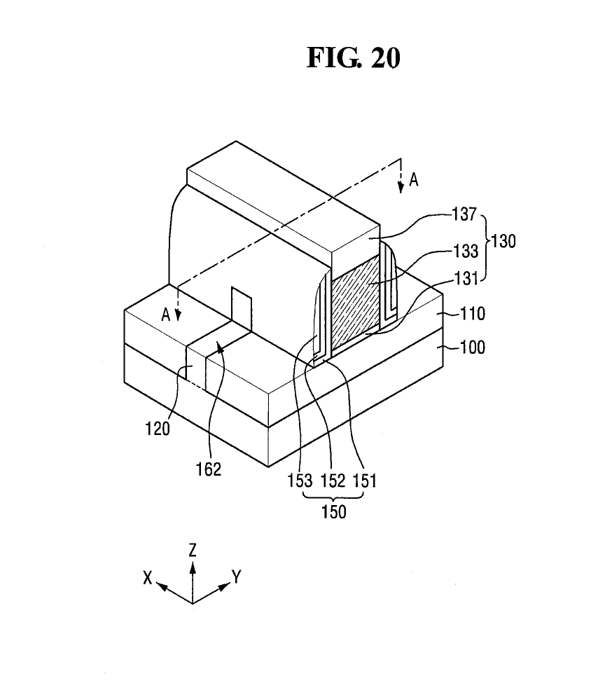

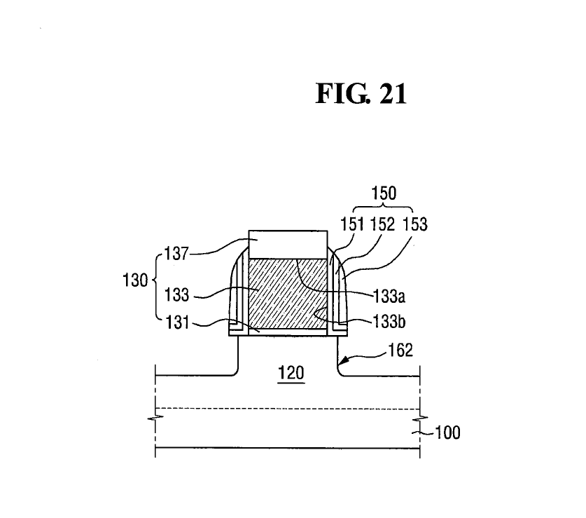

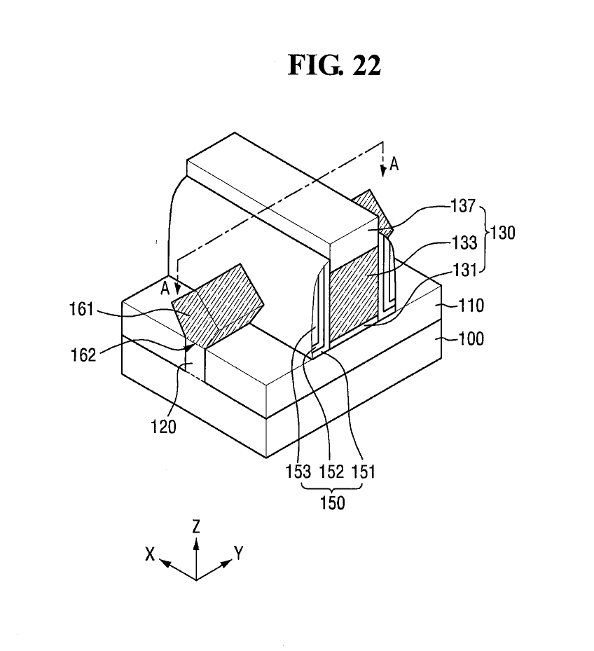

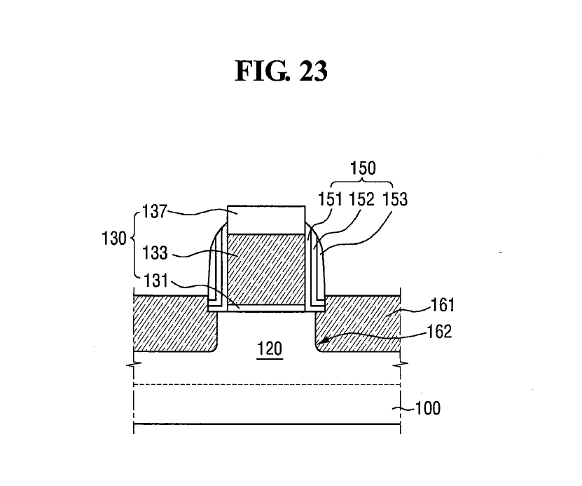

FIGS. 10 to 25 are views illustrating intermediate steps of a method for fabricating a semiconductor device according to some embodiments of the present inventive concept. Here, FIG. 16 is a cross-sectional view taken along the line A-A of FIG. 15. FIG. 21 is a cross-sectional view taken along the line A-A of FIG. 20. FIG. 23 is a cross-sectional view taken along the line A-A of FIG. 22.

Referring to FIG. 10, a first mask pattern 201 may be formed on the substrate 100. A second mask layer 205 may be formed on the substrate 100 on which the first mask pattern 201 is formed.

Specifically, the substrate 100 may be made of, for example, bulk silicon or SOI (Silicon-On-Insulator). In some embodiments, the substrate 100 may be a silicon substrate, or may include another material, such as silicon germanium, indium antimonide, lead telluride, indium arsenide, indium phosphide, gallium arsenide, or gallium antimonide.

Further, the substrate 100 may be provided by forming an epitaxial layer on a base substrate. In the case of forming the fin active pattern 120 as shown in FIG. 3 using the epitaxial layer that is formed on the base substrate, the epitaxial layer may include silicon or germanium that is an elemental semiconductor material. Further, the epitaxial layer may include compound semiconductor, and, for example, may include group IV-IV compound semiconductor or group III-V compound semiconductor. The epitaxial layer including the group IV-IV compound semiconductor may be made of a binary compound including at least two of carbon (C), silicon (Si), germanium (Ge), and tin (Sn), a ternary compound, or a compound including the above-described elements doped with group IV elements. The epitaxial layer including the group III-V compound semiconductor may be made of a binary compound formed through combination of at least one of group III elements, such as aluminum (Al), gallium (Ga), and indium (In), and one of group V elements, such as phosphorus (P), arsenide (As), and antimonium (Sb), a ternary compound, or a quaternary compound.

In the method for fabricating a semiconductor device according to some embodiments of the present inventive concept, it is described that the substrate 100 is a silicon substrate.

The second mask layer 205 may be substantially conformally formed on the upper surface of the substrate 100 on which the first mask pattern 201 is formed. The first mask pattern 201 and the second mask layer 205 may include materials having etch selectivity to each other. For example, the second mask layer 205 may include at least one of silicon oxide, silicon nitride, silicon oxynitride, metal film, photoresist, SOG (Spin On Glass) and/or SOH (Spin On Hard mask). The first mask pattern 201 may be formed of a material that is different from the material of the second mask layer 205 among the above-described materials.

The first mask pattern 201 and the second mask layer 205 may be formed using at least one of a PVD (Physical Vapor Deposition) process, a CVD (Chemical Vapor Deposition) process, an ALD (Atomic Layer Deposition) process, and a spin coating process.

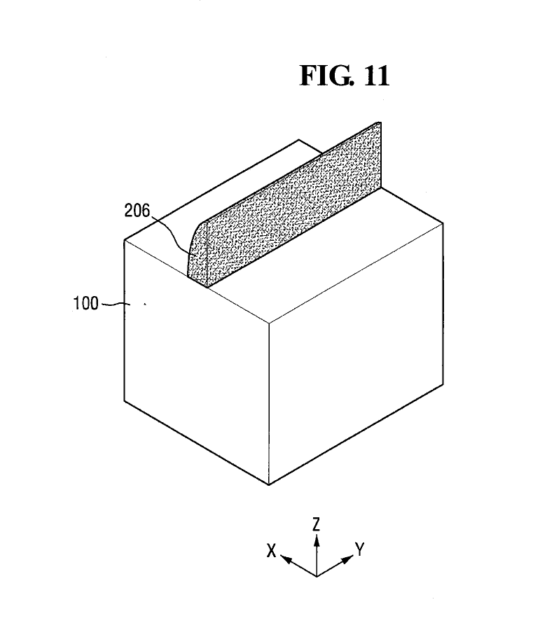

Referring to FIG. 11, through an etching process, a second mask pattern 206 may be formed from the second mask layer 205. The second mask pattern 206 may be in a spacer shape that exposes the first mask pattern 201. The first mask pattern 201 that is exposed by the second mask pattern 206 may be removed to expose the substrate 100 on both sides of the second mask pattern 206.

The removal of the first mask pattern 201 may reduce or possibly minimize the etching of the second mask pattern 206, and may include a selective etching process that can remove the first mask pattern 201.

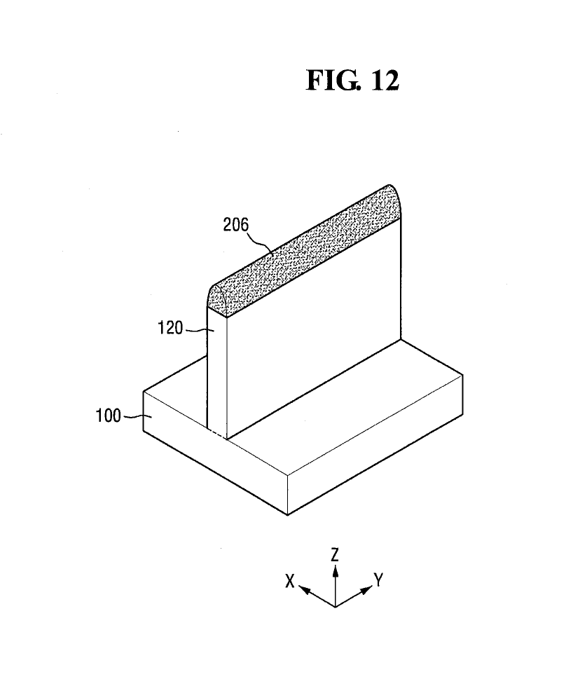

Referring to FIG. 12, the substrate 100 is etched using the second mask pattern 206 as an etching mask. As a part of the substrate 100 is etched, the fin active pattern 120 may be formed on the substrate 100. The fin active pattern 120 may extend in the second direction Y. A recess is formed around the fin active pattern 120 from which a part of the substrate 100 is removed.

It is illustrated that the fin active pattern 120 has a vertical line slope, but is not limited thereto. That is, the side surface of the fin active pattern 120 may have a slope, and thus may be in a tapered shape.

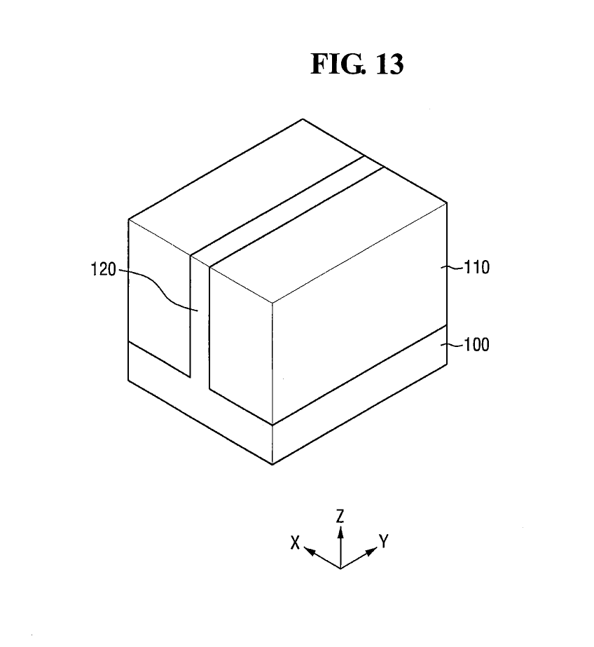

Referring to FIG. 13, the field insulating layer 110 that fills the recess is formed around the fin active pattern 120. The field insulating layer 110 may be formed of at least one of a silicon oxide layer, a silicon nitride layer, and a silicon oxynitride layer.

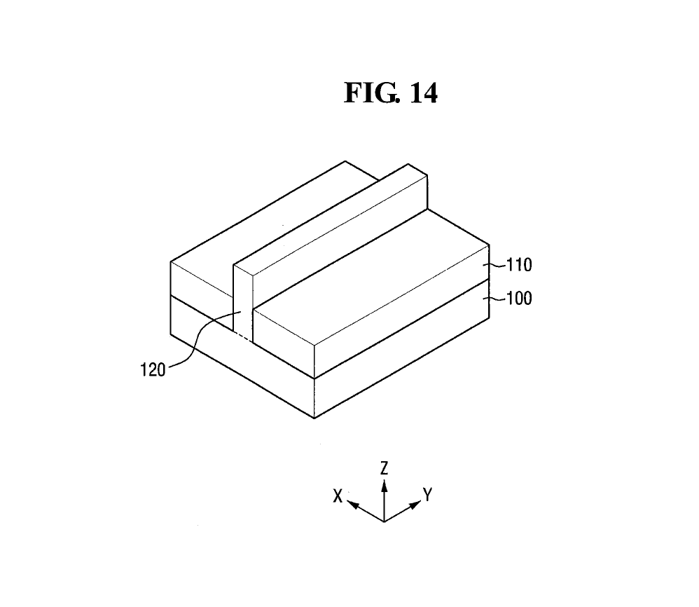

Through a planarization process, the fin active pattern 120 and the field insulating layer may be put on the same plane. During performing of the planarization process, the second mask pattern 206 may be removed, but is not limited thereto. That is, the second mask pattern 206 may be removed before the field insulating layer 110 is formed or after a recess process to be explained through FIG. 14.

Referring to FIG. 14, an upper portion of the fin active pattern 120 is exposed through recessing of the upper portion of the field insulating layer 110. That is, the fin active pattern 120 is formed to project above the field insulating layer 110. The recess process may include a selective etching process.

In some embodiments, a part of the fin active pattern 120 that projects above the field insulating layer 110 may be formed through an epitaxial process. Specifically, after the field insulating layer 110 is formed, a part of the fin active pattern 120 may be formed through an epitaxial process using the upper surface of the fin active pattern 120 that is exposed by the field insulating layer 110 without a recess process as a seed.

Further, doping for adjusting a threshold voltage may be performed on the fin active pattern 120. In the case where a transistor that is formed using the fin active pattern 120 is an NMOS transistor, an impurity doped into the fin active pattern 120 may be boron (B). In the case where a transistor that is formed using the fin active pattern 120 is a PMOS transistor, an impurity doped into the fin active pattern 120 may be phosphorus (P) or arsenide (As).

Referring to FIGS. 15 and 16, a dummy gate structure 130 that crosses the fin active pattern 120 is formed on the fin active pattern 120. The dummy gate structure 130 may be formed to extend in the first direction X.

The dummy gate structure 130 includes a dummy silicon oxide layer 131, a polysilicon layer 133, and a hard mask 137 that are sequentially laminated. That is, the dummy gate structure 130 may be a laminating body of the dummy silicon oxide layer 131, the polysilicon layer 133, and the hard mask 137 that extend in the first direction X.

The dummy gate structure 130 may be formed using the hard mask 137 as an etching mask.

It is illustrated that the dummy silicon oxide layer 131 is formed on not only the circumference of the fin active pattern 120 but also the field insulating layer 110, but is not limited thereto. That is, the dummy silicon oxide layer 131 may be formed only on the side surface and the upper surface of the fin active pattern 120 that projects above the field insulating layer 110.

Further, it is illustrated that the dummy silicon oxide layer 131 is not formed on the fin active pattern 120 that does not overlap the dummy gate structure 130, but is not limited thereto. That is, the dummy silicon oxide layer 131 may be formed on the entire side surface and the entire upper surface of the fin active pattern 120 that projects above the field insulating layer 110.

The dummy silicon oxide layer 131 may serve to protect the fin active pattern 120 that is used as a channel region in the subsequent process.

The polysilicon layer 133 may be formed on the dummy silicon oxide layer 131. The polysilicon layer 133 may overlap the dummy gate structure 130 and may entirely cover the fin active pattern 120 that projects above the field insulating layer 110. In other words, the height measured from the field insulating layer 110 to the upper surface of the fin active pattern 120 is smaller than the height measured from the field insulating layer 110 to the upper surface of the polysilicon layer 133.

The polysilicon layer 133 and the dummy silicon oxide layer 131 may have high etch selectivity. Accordingly, in the case where the polysilicon layer 133 remains on the upper surface of the fin active pattern 120, the polysilicon layer 133 is removed, but the dummy silicon oxide layer 131 on the lower portion remains without being etched in the subsequent process of forming a trench for forming a replacement metal gate. Through this, the fin active pattern 120 on the lower portion of the dummy silicon oxide layer 131 can be protected.

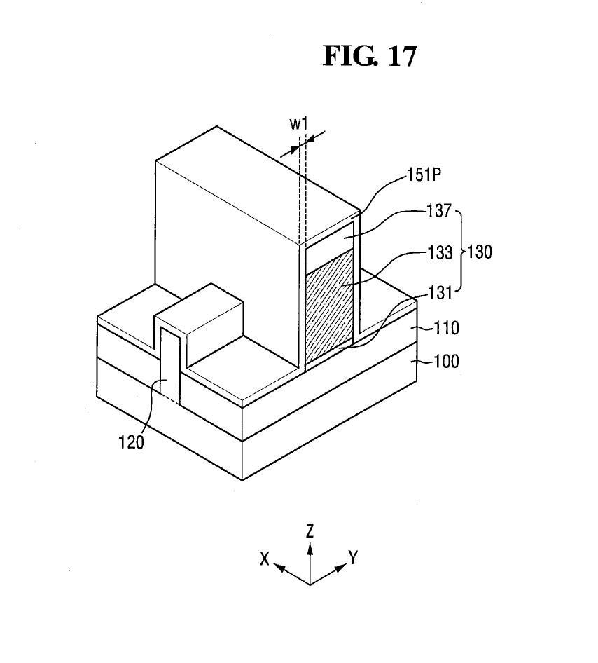

The hard mask 137 is formed on the polysilicon layer 133. The hard mask 137 may include, for example, silicon nitride (SiN), but is not limited thereto. Further, the hard mask 137 may include an etch resistant material than first to third spacer layers 151p to 153p to be explained with reference to FIGS. 17 to 19.

Referring to FIG. 17, a first spacer layer 151p that covers the fin active pattern 120 and the dummy gate structure 130 is formed.

The first spacer layer 151p may be conformally formed on the side surface and the bottom surface of the dummy gate structure 130, the side surface and the bottom surface of the fin active pattern 120, and the field insulating layer 110.

The first spacer layer 151p may include a low-k material and, for example, may include at least one of SiN, SiCN, SiOCN, and SiOC including carbon, but is not limited thereto. The first spacer layer 151p may be formed, for example, using the CVD or ALD process.

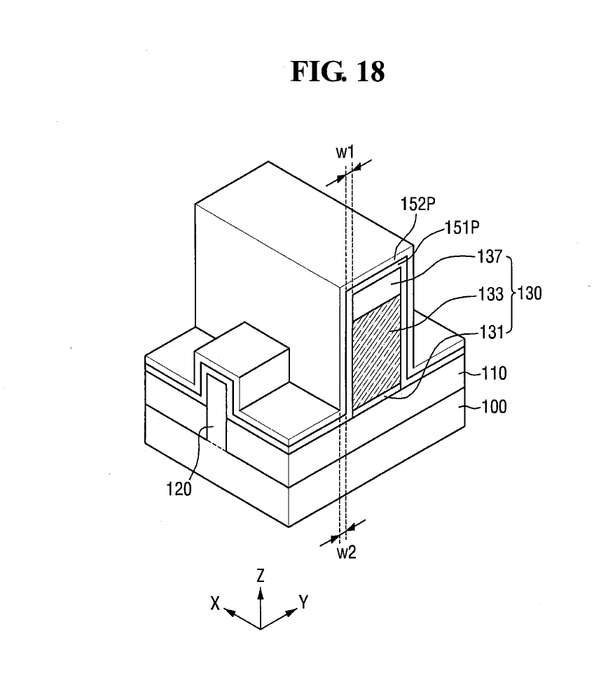

Referring to FIG. 18, a second spacer layer 152p that covers the fin active pattern 120, the dummy gate structure 130, and the first spacer layer 151p is formed. The second spacer layer 152p may be conformally formed on the first spacer layer 151p.

The second spacer layer 152p may include a low-k material and, for example, may include at least one of SiOCN and SiOC including carbon and oxygen, but is not limited thereto. The carbon concentration of the second spacer layer 152p may be lower than the carbon concentration of the first spacer layer 151p, and the oxygen concentration of the second spacer layer 152p may be higher than the oxygen concentration of the first spacer layer 151p. The second spacer layer 152p may be formed, for example, using the CVD or ALD process.

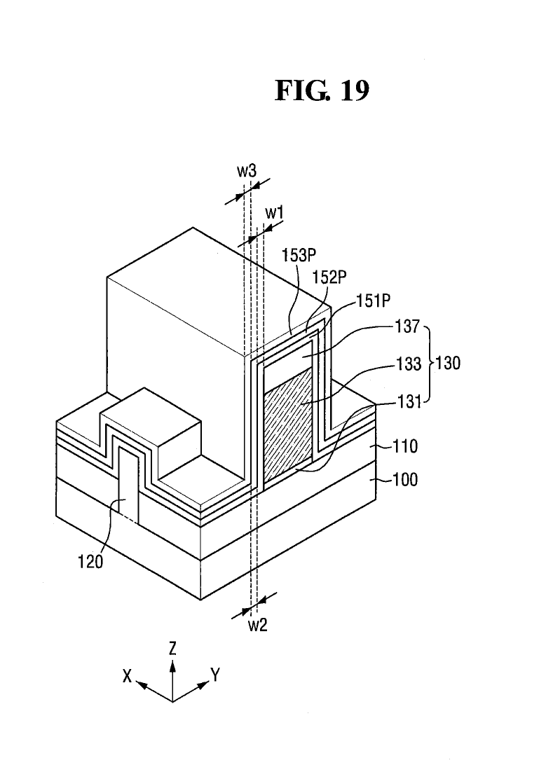

Referring to FIG. 19, a third spacer layer 153p that covers the fin active pattern 120, the dummy gate structure 130, the first spacer layer 151p, and the second spacer layer 152p is formed. The third spacer layer 153p may be conformally formed on the second spacer layer 152p.

The third spacer layer 153p may include a low-k material, and for example, may include at least one of SiOCN and SiOC including carbon and oxygen, but is not limited thereto. The carbon concentration of the third spacer layer 153p may be higher than the carbon concentration of the second spacer layer 152p, and the oxygen concentration of the third spacer layer 153p may be lower than the oxygen concentration of the second spacer layer 152p. The third spacer layer 153p may be formed, for example, using the CVD or ALD process. The third spacer layer 153p may be substantially the same as the first spacer layer 151p.

The dielectric constant of the first to third spacer layers 151p to 153p may be equal to or higher than about 3.8 and equal to or lower than about 5.5. The second spacer layer 152p may have the dielectric constant that is lower than the dielectric constants of the first spacer layer 151p and the third spacer layer 153p.

Referring to FIGS. 20 and 21, the first gate spacer 150 may be formed on the side surface of the dummy gate structure 130, and the hard mask 137 may be exposed.

Further, a recess 162 is formed on the side surface of the dummy gate structure 130. Specifically, the recess 162 is formed on the side surface of the first gate spacer 150 and is formed in the fin active pattern 120.

The first gate spacer 150 on the side surface of the dummy gate structure 130 and the recess 162 in the fin active pattern 120 may be simultaneously or concurrently formed. That is, when the recess 162 is formed, the first gate spacer 150 may also be formed.

Since the first gate spacer 150 is formed by etching the first to third spacer layers 151p to 153p of FIGS. 17 to 19, the first gate spacer 150 may include a material that is different from the material of the hard mask 137. First to third spacers 151 to 153 may be formed through etching of the first gate spacer 150. Further, in the method for fabricating a semiconductor device according to some embodiments of the present inventive concept, the hard mask 137 may include an etch resistant material than the first gate spacer 150. The etching may be a dry etching, and the hard mask 137 may include a dry etch resistant material than the first gate spacer 150.

In FIGS. 20 and 21, the height of the first gate spacer 150 from the upper surface of the field insulating layer 110 is lower than the height measured from the upper surface of the field insulating layer 110 to the upper surface of the dummy gate structure 130, i.e., to the upper surface of the hard mask 137.

When the first gate spacer 150 is formed on the side surface of the dummy gate structure 130, a fin spacer may also be formed on the side surface of the fin active pattern 120 that does not overlap the dummy gate structure 130. However, in order to form the recess 162 in the fin active pattern 120, the fin spacer that is formed on the side surface of the fin active pattern 120 may be removed. While the fin spacer that is formed on the side surface of the fin active pattern 120 is removed, the height of the first gate spacer 150 is lowered, and a part of the hard mask is removed.

In this case, since the hard mask 137 includes an etch resistant material than the first gate spacer 150, the thickness of removal of the hard mask 137 becomes smaller than the height of removal of the first gate spacer 150. Through this, the height of the first gate spacer 150 becomes lower than the height of the dummy gate structure 130.

FIGS. 20 and 21 illustrate that the first gate spacer 150 overlaps the dummy silicon oxide layer 131 and the polysilicon layer 133 of the dummy gate structure 130, but does not overlap the hard mask 137. However, this is merely for convenience in explanation, and the overlapping of the first gate spacer 150 is not limited thereto. That is, the first gate spacer 150 may overlap the hard mask 137 depending on the etching process condition to form the first gate spacer 150.

FIG. 21 illustrates that the fin active pattern 120 is undercut on the lower portions of the dummy gate structure 130 and the first gate spacer 150, but is not limited thereto.

Referring to FIGS. 22 and 23, the elevated source/drain 161 is formed in the recess 162 using an epitaxial growth. The elevated source/drain 161 that is formed in the recess 162 is positioned on the side surface of the dummy gate structure 130.

Through the epitaxial growth, the elevated source/drain 161 is selectively grown on the exposed fin active pattern 120, but the polysilicon layer 133 is not epitaxially grown by the first gate spacer 150 that does not generate a shoulder loss in the dry growth.

If the shoulder loss occurs to reduce the vertical height of the first gate spacer 150 greater than that as intended, the polysilicon layer 133 may be exposed. In this case, since the polysilicon layer 133 includes a crystal plane like monocrystalline silicon, a semiconductor pattern is grown even on the exposed polysilicon layer. As described above, the semiconductor pattern that is parasitically formed on an upper portion of the dummy gate structure causes a nodule defect and the like. Due to such a nodule defect, the operation performance of the semiconductor device is deteriorated, and the processing yield is also lowered.

However, according to the present inventive concept, the second spacer 152 of the first gate spacer 150 can reduce or possibly prevent the nodule defect through reducing or possibly preventing the shoulder loss, and thus the operation performance of the semiconductor device and the processing yield can be possibly prevented from being deteriorated.

Further, the second spacer 152 is weak to the wet etching process, and the lower portion of the second gate spacer 152 having an “L” shape may be damaged by the wet etching process. However, in order to possibly prevent the polysilicon layer 133 from being exposed through the wet etching process, the first spacer 151 that is strong against the wet etching is additionally formed, and thus the short circuit of the gate electrode 147 and the elevated source/drain 161 due to the poly tailing can be reduced or possibly prevented in advance. Accordingly, the operation performance of the semiconductor device and the processing yield can be possibly prevented from being deteriorated.

In the case where the transistor that is formed using the fin active patter 120 is a PMOS transistor, the elevated source/drain 161 may include a compressive stress material. For example, in comparison to Si, the compressive stress material may be a material having a high lattice constant, and may be, for example, SiGe. The compressive stress material may apply compressive stress to the fin active pattern 120 to improve carrier mobility of the channel region.

In some embodiments, in the case where the transistor that is formed using the fin active pattern 120 is an NMOS transistor, the elevated source/drain 161 may be made of the same material as the substrate 100, or may be made of a tensile stress material. For example, in the case where the substrate 100 is made of Si, the elevated source/drain 161 may be Si or a material having a lower lattice constant than the lattice constant of Si (e.g., SiC).

When the elevated source/drain 161 is formed, if needed, an impurity may be in-situ doped into the elevated source/drain 161 during the epitaxial process.

The elevated source/drain 161 may have at least one of a diamond shape, a circular shape, and a rectangular shape. FIG. 22 illustrates a diamond shape (or pentagonal shape or hexagonal shape) as an example.

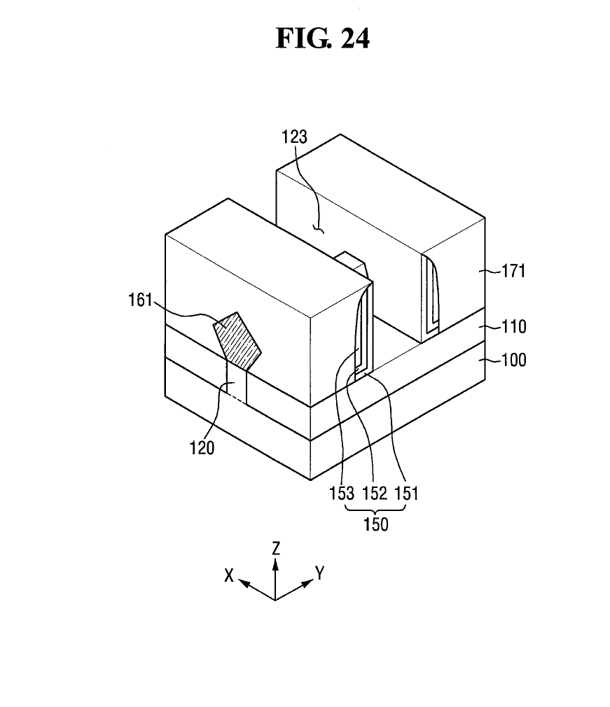

Referring to FIG. 24, the interlayer insulating layer 171 that covers the elevated source/drain 161 and the dummy gate structure 130 is formed on the field insulating layer 110.

The interlayer insulating layer 171 may include, for example, at least one of a low-k material, an oxide layer, a nitride layer, and an oxynitride layer. The low-k material may be, for example, FOX (Flowable Oxide), TOSZ (Tonen SilaZen), USG (Undoped Silica Glass), BSG (Gorosilica Glass), PSG (PhosphoSilica Glass), BPSG (BoroPhosphoSilica Glass), PRTEOS (Plasma Enhanced Tetra Ethyl Ortho Silicate), FSG (Fluoride Silicate Glass), HDP (High Density Plasma), PEOS (Plasma Enhanced Oxide), FCVD (Flowable CVD), or a combination thereof, but is not limited thereto.

Then, the interlayer insulating layer 171 is planarized until the upper surface of the polysilicon layer 133 is exposed. As a result, the hard mask 137 may be removed, and the upper surface of the polysilicon layer 133 may be exposed.

Then, the trench 123 that crosses the fin active pattern 120 is formed through removal of the polysilicon layer 133 and the dummy silicon oxide layer 131.

That is, through removal of the dummy gate structure 130, the trench 123 that crosses the fin active pattern 120 is formed on the fin active pattern 120.

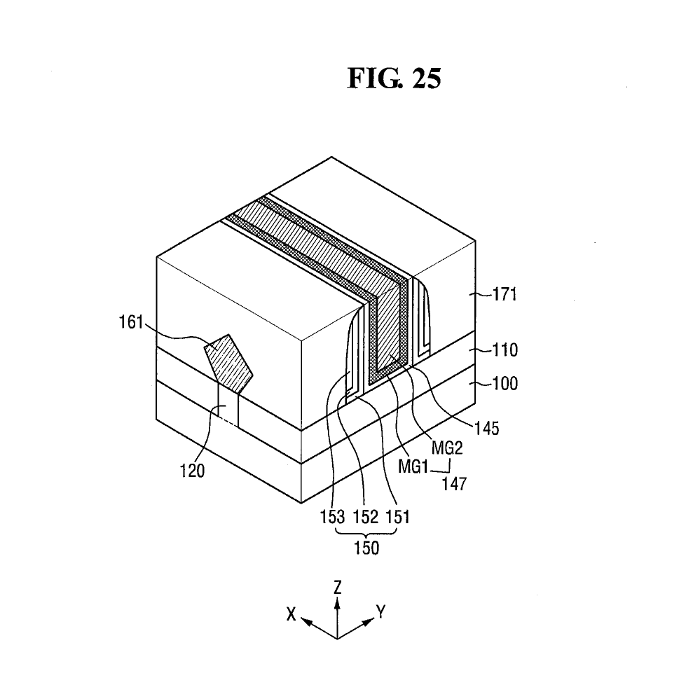

Referring to FIG. 25, the gate insulating layer 145 and the replacement gate electrode 147 are formed in the trench 123.

The gate insulating layer 145 may be substantially conformally formed along the side wall and the lower surface of the trench 123. The gate insulating layer 145 may include a high-k material having a higher dielectric constant than the dielectric constant of the silicon oxide layer. For example, the gate insulating layer 145 may include at least one of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, but is not limited thereto.

The gate electrode 147 may include metal layers MG1 and MG2. As illustrated, the gate electrode 147 may include two or more laminated metal layers MG1 and MG2. The first metal layer MG1 serves to adjust a work function, and the second metal layer MG2 serves to fill the space that is formed by the first metal layer MG1. For example, the first metal layer MG1 may include at least one of TiN, TaN, TiC, and TaC. Further, the second metal layer MG2 may include W or Al.

Hereinafter, referring to FIGS. 1 to 3 and 26, a semiconductor device according to some embodiments of the present inventive concept will be described.

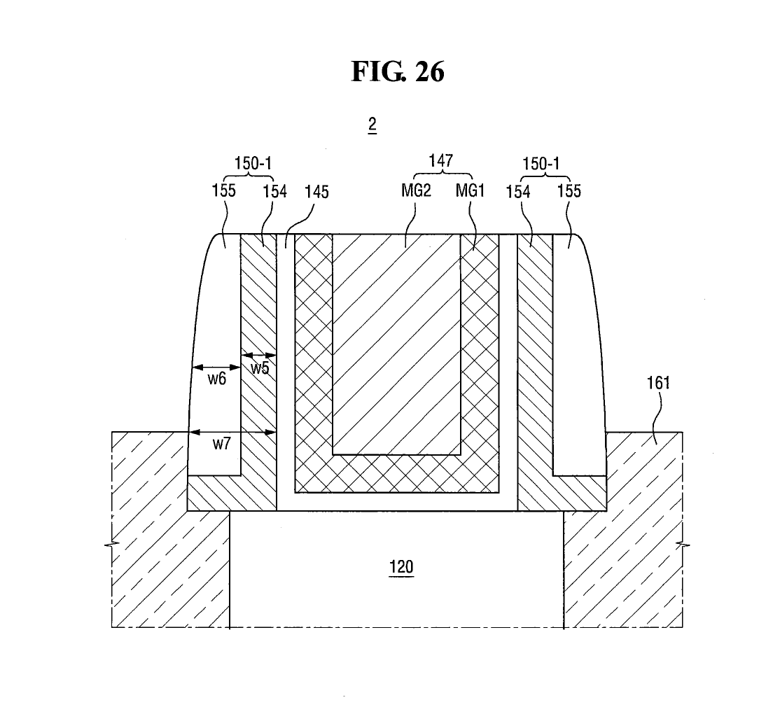

FIG. 26 is a cross-sectional view of a semiconductor device according to some embodiments of the present inventive concept.

Referring to FIGS. 1 to 3 and 26, a semiconductor device 2 according to some embodiments of the present inventive concept includes a second gate spacer 150-1 having a structure that is different from the structure of the first gate spacer 150 according to some embodiments.

Referring to FIG. 26, the second gate spacer 150-1 may include a fourth spacer 154 and a fifth spacer 155.

The fourth spacer 154 may be positioned most adjacently to the gate electrode 147 on the innermost wall of the second gate spacer 150-1, but is not limited thereto. Another layer may be formed between the fourth spacer 154 and the gate electrode 147. That is, the fourth spacer 154 may be positioned on an inner side than the fifth spacer 155, i.e., on a side that is close to the gate electrode 147.

The fourth spacer 154 may include SiOCN or SiOC that includes carbon and oxygen. The fourth spacer 154 includes a similar material to the material of the fifth spacer 155, but the ratios of constituent elements thereof may differ from each other. Specifically, the ratio of Si, O, C, or N of the fourth spacer 154 may differ from that of the fifth spacer 155.

For example, the fourth spacer 154 may have a carbon concentration of about 0% to about 6% and an oxygen concentration of about 35% to about 50%.

The fourth spacer 154 may be in an “L” shape. That is, an extending portion may be formed in a horizontal direction in which the fourth spacer 154 goes out from the gate electrode 147.

The fifth spacer 155 may be positioned on the outermost wall of the second gate spacer 150-1. That is, the fifth spacer 155 may be positioned on the outer side than the fourth spacer 154, i.e., on the side that is far from the gate electrode 147.

The fifth spacer 155 may include SiN, SiCN, SiOCN or SiOC that includes carbon.

The fifth spacer 155 may be in an “I” shape. That is, the fifth spacer 155 may be formed only in a vertical shape without the extending portion formed in the horizontal direction in which the fifth spacer 155 goes out from the gate electrode 147. The side surface of the fifth spacer 155 may have a vertical shape or may have a slope. That is, the fifth spacer 155 may be in a tapered shape.

The fifth spacer 155 may have a carbon concentration of about 6% to about 21% and an oxygen concentration of about 25% to about 40%. However, this is merely example, and the concentrations of carbon and oxygen are not limited thereto. That is, the fifth spacer 155 has a higher carbon concentration than the carbon concentration of the fourth spacer 154 and a lower oxygen concentration than the oxygen concentration of the fourth spacer 154.

The fifth spacer 155 may be a layer having sufficient carbon in comparison to the fourth spacer 154. Further, the fifth spacer 155 may be a layer having less sufficient oxygen in comparison to the fourth spacer 154. That is, the carbon concentration of the fourth spacer 154 may be lower than the carbon concentration of the fifth spacer 155, and the oxygen concentration of the fourth spacer 154 may be higher than the oxygen concentration of the fifth spacer 155.

The dielectric constant may be changed depending on the composition of the materials included in the spacer. Accordingly, the dielectric constant of the fourth spacer 154 may be lower than the dielectric constant of the fifth spacer 155.

In the second gate spacer 150-1 of the semiconductor device 2 according to some embodiments of the present inventive concept, the etch rates of the fourth spacer 154 and the fifth spacer 155 may be different from each other depending on the carbon and oxygen concentrations.

In the case of the fifth spacer 155 having a relatively high carbon concentration, the wet etch rate thereof may be lower than that of the fourth spacer 154. In contrast, in the case of the fourth spacer 154 having a relatively low carbon concentration, the wet etch rate thereof may be higher than that of the fifth spacer 155.

For example, the fourth spacer 154 that is formed through a deposition process at 600° C. may have the wet etch rate of about 32.6±5 Å/min on the wet etching surface by 100:1 HF. The fifth spacer 155 that is formed through a deposition process at 600° C. may have the wet etch rate of about 5.9±2 Å/min on the wet etching surface by 100:1 HF.

Further, the fourth spacer 154 that is formed through a deposition process at 630° C. may have the wet etch rate of about 25.5±5 Å/min on the wet etching surface by 100:1 HF. The fifth spacer 155 that is formed through a deposition process at 630° C. may have the wet etch rate of about 4.0±2 Å/min on the wet etching surface by 100:1 HF.

That is, the fifth spacer 155 as described above may endure well against the wet etching.

Further, in the case of the fifth spacer 155 having a relatively low oxygen concentration, the dry etch rate thereof may be higher than that of the fourth spacer 154. In contrast, in the case of the fourth spacer 154 having a relatively high oxygen concentration, the dry etch rate thereof may be lower than that of the fifth spacer 155. Accordingly, the fourth spacer 154 can endure well against the dry etching.

The second gate spacer 150-1 may be formed by first forming a spacer layer and making a vertical portion thereof remain through the dry etching. However, in the process of forming the second gate spacer 150-1, a shoulder loss of the second gate spacer 150-1 may unintentionally occur, i.e., the vertical height of the second gate spacer 150-1 may be reduced greater than that as intended.

The second gate spacer 150-1 serves to possibly prevent a dummy gate that includes a polysilicon layer from being exposed in a gate last process. However, if the shoulder loss occurs as described above, the polysilicon layer of the dummy gate may be exposed.

The elevated source/drain 161 of the semiconductor device 2 is formed using an epitaxial growth. In this case, since the polysilicon layer includes a crystal plane like monocrystalline silicon, a semiconductor pattern is grown even on the exposed polysilicon layer. As described above, the semiconductor pattern that is parasitically formed on the upper portion of the dummy gate structure causes a nodule defect and the like. Due to such a nodule defect, the operation performance of the semiconductor device is deteriorated, and the processing yield is also lowered.

Accordingly, the second gate spacer 150-1 of the semiconductor device 2 according to some embodiments of the present inventive concept may have the low dry etch rate through the fourth spacer 154. That is, since the fourth spacer 154 has the low dry etch rate, the shoulder loss can be possibly prevented from occurring due to the dry etching in the process of forming the second gate spacer 150-1. Accordingly, in the case where a plurality of gate electrodes 147 is provided, a short circuit, i.e., a nodule defect, can be possibly prevented from occurring.

The second gate spacer 150-1 may be formed by depositing two layers at a time and etching the deposited layers at a time to form a dual layer. This method can reduce waste of processes in comparison to the method in which spacers are formed one by one, and can possibly prevent other patterns from being damaged due to excessive etching.

Referring again to FIG. 26, the fourth spacer 154 may be formed with a fifth width W5, and the fifth spacer 155 may be formed with a sixth width W6. The second gate spacer 150-1 may be formed with a seventh width W7. In this case, the fifth to seventh widths W5 to W7 may not be constant, and may mean representative values, such as average values or middle values, but are not limited thereto.

For example, the seventh width W7 may be about 110 to about 150 Å. The width of the whole second gate spacer 150-1 may be constant to protect the internal structure against a plurality of etching processes. Further, the seventh width W7 of the second gate spacer 150-1 may be thinner than a predetermined thickness in consideration of the whole overlap margin.

For example, the sixth width W6 may be about 20 to about 120 Å. A fine pinhole may be formed in the fifth spacer 155. The pinhole is a hole that is formed in the fifth spacer 155, and in order for the fifth spacer 155 to perform insulation function, the thickness of the fifth spacer 155 may be equal to or larger than a predetermined thickness. Further, the fifth spacer 155 may be thinner than a predetermined thickness in consideration of the overlap margin.

For example, the fifth width W5 may be about 20 to about 120 Å. The fourth spacer 154 may be determined in consideration of the existence of the pinhole and the whole thickness of the second gate spacer 150-1, i.e., limitation of the seventh width W7, but is not limited thereto.

Since the semiconductor device 2 according to some embodiments of the present inventive concept reduces the capacitive coupling through the low dielectric constant of the second gate spacer 150-1, the AC performance of the semiconductor device 2 can be improved. Further, in the dry and wet etching processes, the upper portion and the lower portion of the second gate spacer 150-1 can be possibly prevented from being unintentionally damaged, and thus the yield of the semiconductor device 2 can be possibly prevented from being deteriorated.

Hereinafter, referring to FIGS. 10 to 16 and 27 to 29, a method for fabricating a semiconductor device according to some embodiments of the present inventive concept will be described.

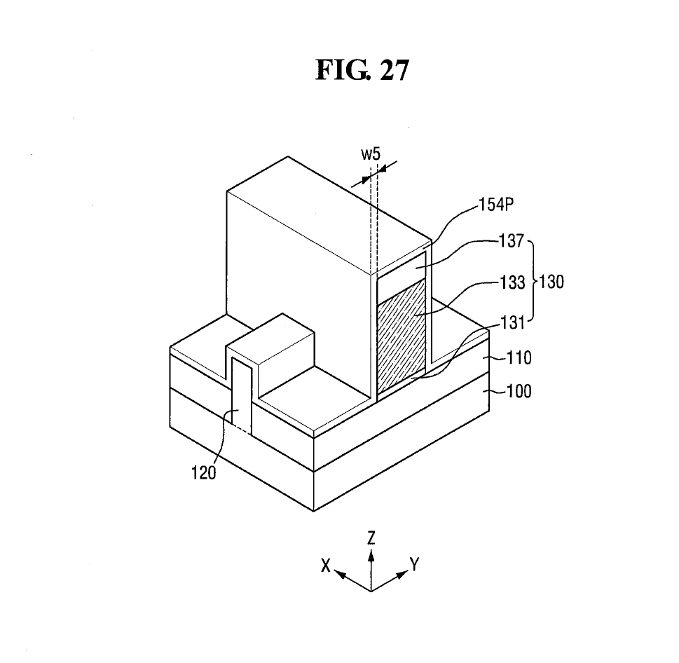

FIGS. 27 to 29 are views illustrating intermediate steps of a method for fabricating a semiconductor device according to some embodiments of the present inventive concept.

Referring to FIG. 27, a fourth spacer layer 154p that covers the fin active pattern 120 and the dummy gate structure 130 is formed.

The fourth spacer layer 154p may be conformally formed on the side surface and the bottom surface of the dummy gate structure 130, the side surface and the bottom surface of the fin active pattern 120, and the field insulating layer 110.

The fourth spacer layer 154p may include a low-k material and, for example, may include at least one of SiOCN and SiOC including carbon and oxygen, but is not limited thereto. The carbon concentration of the fourth spacer layer 154p may be lower than the carbon concentration of the fifth spacer layer 155p, and the oxygen concentration of the fourth spacer layer 154p may be higher than the oxygen concentration of the fifth spacer layer 155p. The fourth spacer layer 154p may be formed, for example, using the CVD or ALD process.

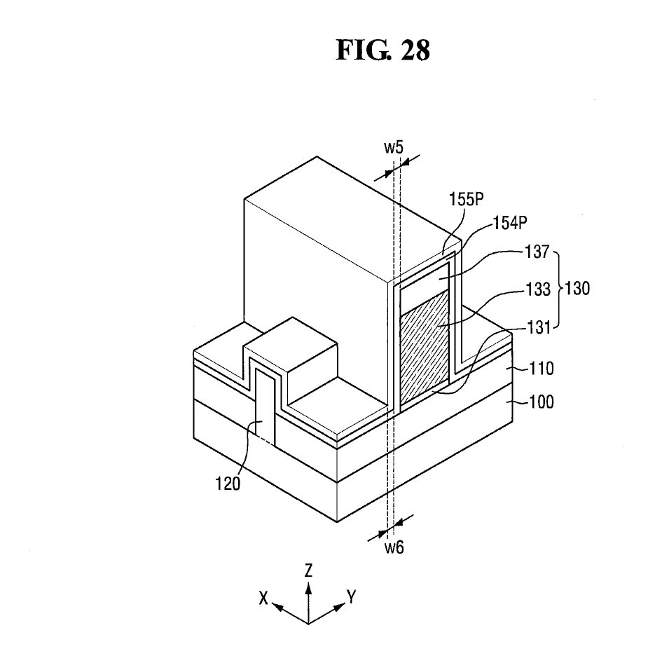

Referring to FIG. 28, the fifth spacer layer 155p that covers the fin active pattern 120, the dummy gate structure 130, and the fourth spacer layer 154p is formed. The fifth spacer layer 155p may be conformally formed on the fourth spacer layer 154p.

The fifth spacer layer 155p may include a low-k material and, for example, may include at least one of SiOCN and SiOC including carbon and oxygen, but is not limited thereto. The carbon concentration of the fifth spacer layer 155p may be higher than the carbon concentration of the fourth spacer layer 154p, and the oxygen concentration of the fifth spacer layer 155p may be lower than the oxygen concentration of the fourth spacer layer 154p. The fifth spacer layer 155p may be formed, for example, using the CVD or ALD process.

The dielectric constant of the fourth and fifth spacer layers 154p and 155p may be equal to or higher than about 3.8 and equal to or lower than about 5.5. The fourth spacer layer 154p may have the dielectric constant that is lower than the dielectric constant of the fifth spacer layer 155p.

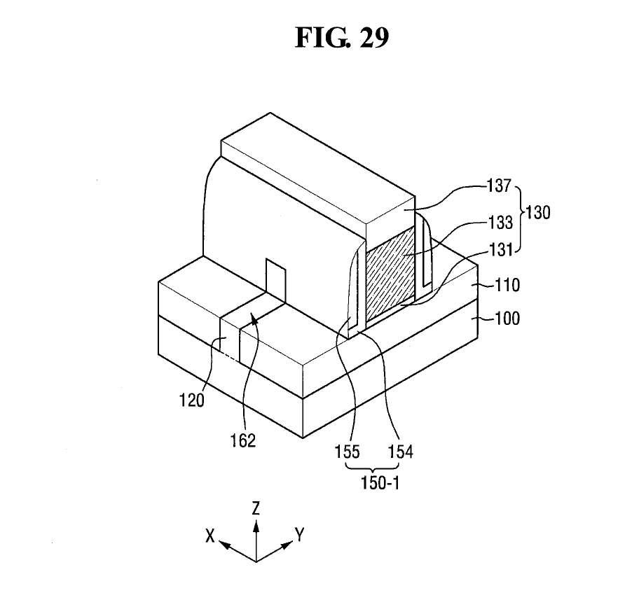

Referring to FIG. 29, the second gate spacer 150-1 may be formed on the side surface of the dummy gate structure 130, and the hard mask 137 may be exposed.

Further, a recess 162 is formed on the side surface of the dummy gate structure 130. Specifically, the recess 162 is formed on the side surface of the second gate spacer 150-1 and is formed in the fin active pattern 120.

The second gate spacer 150-1 on the side surface of the dummy gate structure 130 and the recess 162 in the fin active pattern 120 may be simultaneously or concurrently formed. That is, when the recess 162 is formed, the second gate spacer 150-1 may also be formed.

Since the second gate spacer 150-1 is formed by etching the fourth and fifth spacer layers 154p and 155p, the second gate spacer 150-1 includes a material that is different from the material of the hard mask 137. Fourth and fifth spacers 154 and 155 may be formed through etching of the second gate spacer 150-1. Further, in the method for fabricating a semiconductor device according to some embodiments of the present inventive concept, the hard mask 137 may include an etch resistant material than the second gate spacer 150-1. The etching may be a dry etching, and the hard mask 137 may include a dry etch resistant material than the second gate spacer 150-1.

In FIG. 29, the height of the second gate spacer 150-1 from the upper surface of the field insulating layer 110 is lower than the height measured from the upper surface of the field insulating layer 110 to the upper surface of the dummy gate structure 130, i.e., to the upper surface of the hard mask 137.

When the second gate spacer 150-1 is formed on the side surface of the dummy gate structure 130, a fin spacer may also be formed on the side surface of the fin active pattern 120 that does not overlap the dummy gate structure 130. However, in order to form the recess 162 in the fin active pattern 120, the fin spacer that is formed on the side surface of the fin active pattern 120 may be removed. While the fin spacer that is formed on the side surface of the fin active pattern 120 is removed, the height of the second gate spacer 150-1 is lowered, and a part of the hard mask is removed.

In this case, since the hard mask 137 includes an etch resistant material than the second gate spacer 150-1, the thickness of the hard mask 137 removed becomes smaller than the height of the second gate spacer 150-1 removed. Through this, the height of the second gate spacer 150-1 becomes lower than the height of the dummy gate structure 130.

FIG. 29 illustrates that the second gate spacer 150-1 overlaps the dummy silicon oxide layer 131 and the polysilicon layer 133 of the dummy gate structure 130, but does not overlap the hard mask 137. However, this is merely for convenience in explanation, and the overlapping of the second gate spacer 150-1 is not limited thereto. That is, the second gate spacer 150-1 may overlap the hard mask 137 depending on the etching process condition to form the second gate spacer 150-1.

Hereinafter, referring to FIGS. 1 to 3 and 30, a semiconductor device according to some embodiments of the present inventive concept will be described.

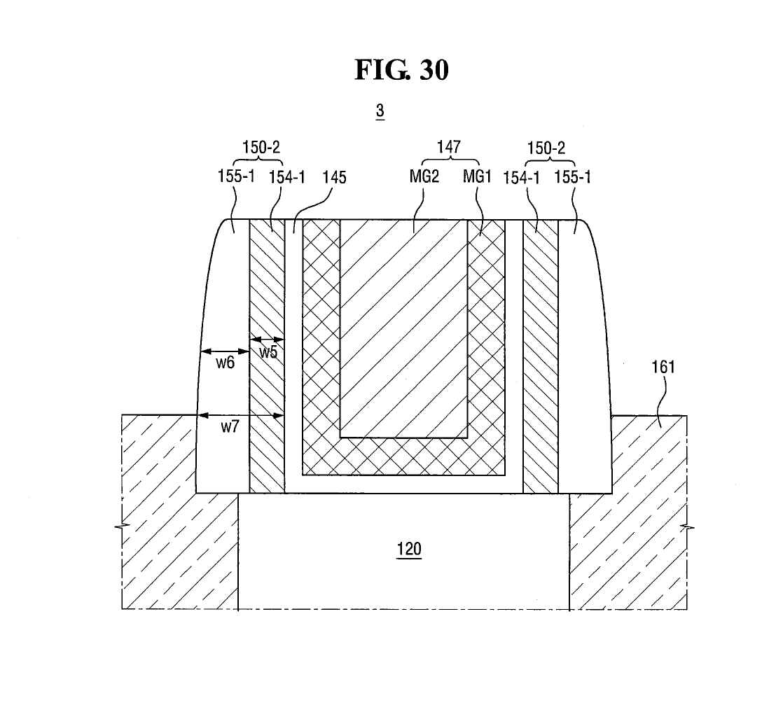

FIG. 30 is a cross-sectional view of a semiconductor device according to some embodiments of the present inventive concept.

Referring to FIGS. 1 to 3 and 30, a semiconductor device 3 according to some embodiments of the present inventive concept includes a third gate spacer 150-2 having a structure that is different from the structure of the second gate spacer 150-1 according to some embodiments.

Referring to FIG. 30, the third gate spacer 150-2 may include a sixth spacer 154-1 and a seventh spacer 155-1.

The sixth spacer 154-1 may be positioned most adjacently to the gate electrode 147 on the innermost wall of the third gate spacer 150-2, but is not limited thereto. Another layer may be formed between the sixth spacer 154-1 and the gate electrode 147. That is, the sixth spacer 154-1 may be positioned on an inner side than the seventh spacer 155-1, i.e., on a side that is close to the gate electrode 147.

The sixth spacer 154-1 may include SiOCN or SiOC that includes carbon and oxygen. The sixth spacer 154-1 includes a similar material to the material of the seventh spacer 155-1, but the ratios of constituent elements thereof may differ from each other. Specifically, the ratio of Si, O, C, or N of the sixth spacer 154-1 may differ from that of the seventh spacer 155-1.

The seventh spacer 155-1 may be positioned on the outermost wall of the third gate spacer 150-2. That is, the seventh spacer 155-1 may be positioned on the outer side than the sixth spacer 154-1, i.e., on the side that is far from the gate electrode 147.

The seventh spacer 155-1 may include SiN, SiCN, SiOCN or SiOC that includes carbon.

The sixth spacer 154-1 and the seventh spacer 155-1 may be in an “I” shape. That is, the sixth spacer 154-1 and the seventh spacer 155-1 may be formed only in a vertical shape without the extending portion formed in the horizontal direction in which the sixth spacer 154-1 and the seventh spacer 155-1 go out from the gate electrode 147. The side surfaces of the sixth spacer 154-1 and the seventh spacer 155-1 may have a vertical shape or may have a slope. That is, the seventh spacer 155-1 may be in a tapered shape.

The sixth spacer 154-1 and the seventh spacer 155-1 may have the same width as the width of the fourth spacer 154 and the fifth spacer 155 according to some embodiments. That is, the sixth spacer 154-1 may have a fifth width W5, and the seventh spacer 155-1 may have a sixth width W6. The third gate spacer 150-2 may have a seventh width W7. That is, the semiconductor device illustrated in FIG. 30 may be similar to semiconductor device illustrated in FIG. 26 except that the “L” shape of the spacer is changed to the “I” shape.

According to the semiconductor device 3 according to some embodiments of the present inventive concept, the third gate spacer 150-2 includes the sixth spacer 154-1 and the seventh spacer 155-1 of the “I” shape. The sixth spacer 154-1 may be strong against the dry etching, and the seventh spacer 155-1 may be strong against the wet etching. Through the sixth spacer 154-1, the third gate spacer 150-2 does not cause the shoulder loss to occur against the dry etching to possibly prevent the nodule defect.

Further, since the sixth spacer 154-1 is formed in the “I” shape rather than the “L” shape, the lower portion of the third gate spacer 150-2 is possibly prevented from being damaged due to the wet etching, and thus the gate electrode 147 and the elevated source/drain 161 can be possibly prevented from being short-circuited.

For this, the sixth spacer 154-1 may be first formed before the spacer layer for the seventh spacer 155-1 is deposited. That is, the sixth spacer 154-1 may be first formed, the spacer layer for the seventh spacer 155-1 may be deposited, and then the seventh spacer 155-1 may be formed through etching of the spacer layer.

While the present inventive concept has been particularly shown and described with reference to example embodiments thereof, it will be understood by those of ordinary skill in the art that various changes in form and details may be made therein without departing from the spirit and scope of the present inventive concept as defined by the following claims. It is therefore desired that the present embodiments be considered in all respects as illustrative and not restrictive, reference being made to the appended claims rather than the foregoing description to indicate the scope of the inventive concept.

What is claimed is:

1. A semiconductor device comprising:
a fin active pattern protruding from a substrate;
a gate electrode crossing the fin active pattern on the substrate;
a gate spacer on a sidewall of the gate electrode and having a low dielectric constant; and
an elevated source/drain on both sides of the gate electrode on the fin active pattern,
wherein the gate spacer includes first, second and third spacers that are sequentially disposed on the sidewall of the gate electrode and in contact with each other, and
a carbon concentration of the second spacer is lower than carbon concentrations of the first and third spacers.

2. The semiconductor device of claim 1, wherein the carbon concentrations of the first and third spacers are substantially equal.

3. The semiconductor device of claim 1, wherein an oxygen concentration of the second spacer is higher than oxygen concentrations of the first and third spacers.

4. The semiconductor device of claim 3, wherein the oxygen concentrations of the first and third spacers are substantially equal.

5. The semiconductor device of claim 1, wherein the first spacer comprises SiN that includes carbon.

6. The semiconductor device of claim 1, wherein the dielectric constant of the gate spacer is about 3.8 to about 5.5.

7. The semiconductor device of claim 1, wherein the first and third spacers comprise SiOCN or SiOC.

8. The semiconductor device of claim 1, wherein the carbon concentration of the first spacer is about 6% to about 21%.

9. The semiconductor of claim 1, wherein a thickness of the gate spacer is about 110 Å to about 150 Å.

10. The semiconductor device of claim 9, wherein a thickness of the first spacer is about 20 Å to about 50 Å.

11. The semiconductor device of claim 1, wherein the first and second spacers are in an “L” shape, and the third spacer is in an “I” shape.

12. The semiconductor device of claim 1, wherein a dielectric constant of the second spacer is lower than dielectric constants of the first and third spacers.

13. A semiconductor device comprising:
a fin active pattern protruding from a substrate;
a gate electrode crossing the fin active pattern on the substrate;
a gate spacer on a sidewall of the gate electrode and having a low dielectric constant; and
an elevated source/drain on both sides of the gate electrode on the fin active pattern,
wherein the gate spacer includes first and second spacers that are sequentially disposed on the sidewall of the gate electrode and in contact with each other, and
an oxygen concentration of the first spacer is lower than an oxygen concentration of the second spacer.

14. The semiconductor device of claim 13, wherein a wet etch rate of the first spacer is lower than a wet etch rate of the second spacer.

15. The semiconductor device of claim 13, wherein a dry etch rate of the first spacer is higher than a dry etch rate of the second spacer.
